(19) United States
(12) Patent Application Publication
(10) Pub. No.: US 2007/0158842 A1
(43) Pub. Date: Jul. 12, 2007

(54) Integrated circuit package having metallic members intruding into solder balls

(76) Inventor: Chou Hsuan Tsai, Hsin-Chuang City (TW)

Correspondence Address: PRO-TECHTOR INTERNATIONAL SERVICES, 20775 NORADA CT., SARATOGA, CA, 95070, US

(21) Appl. No.: 11/650,103

(22) Filed: Jan. 5, 2007

(30) Foreign Application Priority Data
Jan. 9, 2006 (TW) 095100795

(51) Int. Cl. H01L 23/48

(52) U.S. Cl. 257/737; 257/787; 257/E23.069

(57) ABSTRACT

An integrated circuit package having metallic members intruding into solder balls. The integrated circuit package includes an integrated circuit, an encapsulant, a plurality of solder balls and a plurality of metallic members. A plurality of bonding pads is disposed on an integrated circuit. The encapsulant is made of an insulation material and covers the integrated circuit. A plurality of slots is formed on a bottom surface of the encapsulant. The solder balls are respectively disposed in the slots on the bottom surface of the encapsulant and protrude from the bottom surface of the encapsulant. Each metallic member has a first end, which is electrically connected to a bonding pad of the integrated circuit, and a second end, which protrudes from the bottom surface of the encapsulant and is bent to intrude into a corresponding one of the solder balls to fix the solder ball.

### BACKGROUND OF THE INVENTION

1. Field of the Invention

The invention relates to an integrated circuit package, and more particularly to an integrated circuit package having metallic members intruding into solder balls.

2. Description of the Related Art

Referring to FIG. 1, a conventional integrated circuit package includes an integrated circuit 10, an encapsulant 12 and a plurality of metallic members 14. The encapsulant 12 is made of an insulation material and covers the integrated circuit 10. The metallic members 14 have first ends electrically connected to bonding pads of the integrated circuit 10 and second ends extending out of two sides of the encapsulant 12 to form horizontal pins 15 flush with the bottom surface of the encapsulant 12. The horizontal pins 15 are to be bonded to a circuit board.

Referring to FIG. 2, another conventional integrated circuit package includes an integrated circuit 10, an encapsulant 12, a plurality of bonding pads 16 and a plurality of solder balls 18. The encapsulant 12 is made of an insulation material and covers the integrated circuit 10. Each bonding pad 16 is electrically connected to one bonding pad of the integrated circuit 10 and exposed out of the bottom surface of the encapsulant 12. Each solder ball 18 is bonded to one bonding pad 16 and is to be bonded to a circuit board.

The advantage of disposing the solder balls is that a lot of bonding pads 16 may be electrically connected to the circuit board through the solder balls while the extended horizontal pins may cause the empty solder only if one pin is not leveled. However, the soldering paste has to be applied to the bonding pads 16 in the process of disposing the solder balls and then the solder balls 18 have to be aligned with the bonding pads followed by the heating process. Thus, the manufacturing processes are complicated and the heating processes are performed slowly.

### SUMMARY OF THE INVENTION

It is therefore an object of the invention to provide an integrated circuit package having metallic members intruding into solder balls to fix the solder balls at the second ends of the metallic members without using the heating and bonding processes so that the manufacturing processes may be simplified and speeded up.

The invention achieves the above-identified object by providing an integrated circuit package including an integrated circuit, an encapsulant, a plurality of solder balls and a plurality of metallic members. A plurality of bonding pads is disposed on the integrated circuit. The encapsulant is made of an insulation material and covers the integrated circuit. A plurality of slots is formed on a bottom surface of the encapsulant. The solder balls are respectively disposed in the slots on the bottom surface of the encapsulant and protrude from the bottom surface of the encapsulant. Each metallic member has a first end, which is electrically connected to a bonding pad of the integrated circuit, and a second end, which protrudes from the bottom surface of the encapsulant and is bent to intrude into a corresponding one of the solder balls to fix the solder ball.

The invention will become apparent from the following detailed description of the preferred but non-limiting embodiments. The following description is made with reference to the accompanying drawings.

### BRIEF DESCRIPTION OF THE DRAWINGS

FIG. 1 is a pictorial view showing an integrated circuit package with solder balls.

FIG. 2 is a pictorial view showing another conventional integrated circuit package having solder balls.

FIG. 3 is a pictorial view showing an integrated circuit package having metallic members intruding into solder balls according to a first embodiment of the invention.

FIG. 4 is a cross-sectional view showing the integrated circuit package according to the first embodiment of the invention.

FIG. 5 is a pictorial view showing an integrated circuit package having metallic members intruding into solder balls according to a second embodiment of the invention.

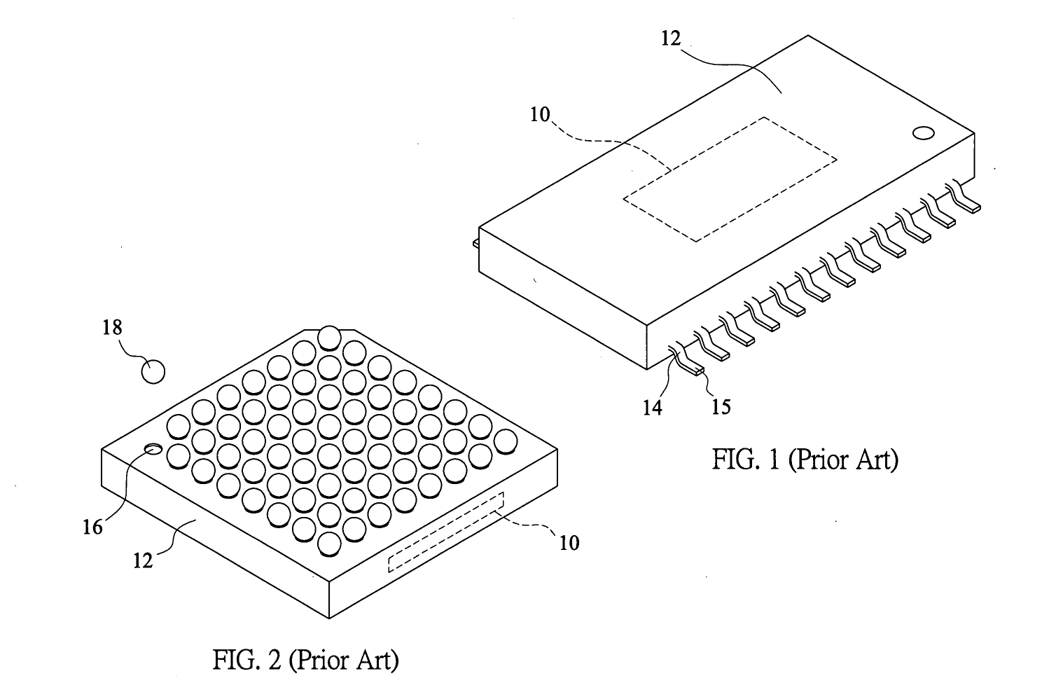

### DETAILED DESCRIPTION OF THE INVENTION

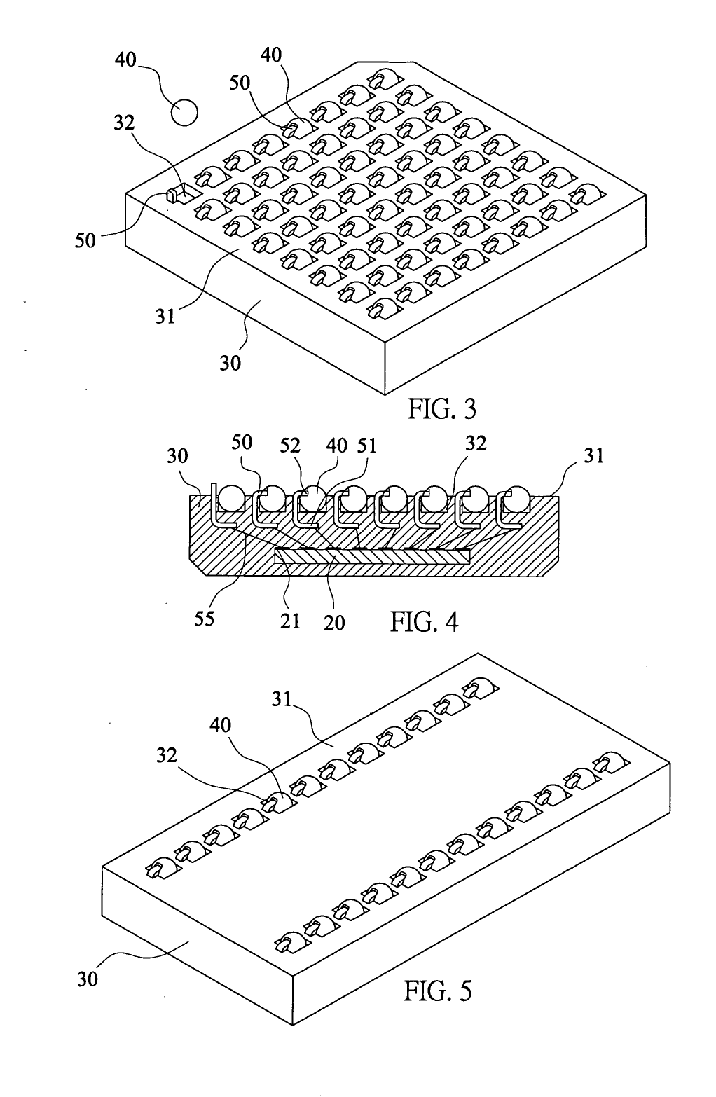

Referring to FIGS. 3 and 4, an integrated circuit package of this embodiment has a square shape and includes an integrated circuit 20, an encapsulant 30, a plurality of solder balls 40 and a plurality of metallic members 50. For the sake of explanation, one of the metallic members 50 is not bent in the drawings.

A plurality of bonding pads 21 is disposed on the integrated circuit 20.

The encapsulant 30 is made of an insulation material, which may be a plastic material, a ceramic material or transparent glass, to cover the integrated circuit 20. The encapsulant 30 has a bottom surface 31 on which a plurality of slots 32 arranged in an array is formed.

Each solder ball 40 is disposed in a corresponding one of the slots 32 on the bottom surface of the encapsulant 30 and protrudes from the bottom surface 31 of the encapsulant.

Each metallic member 50 has a first end 51 and a second end 52. The first end 51 is electrically connected to one of the bonding pads 21 of the integrated circuit 20 through a wire 55. The second end 52 protrudes from the bottom surface 31 of the encapsulant, and is then pressed by a jig to bend and intrude into one of the solder balls 40 to fix the solder ball 40.

According to the above-mentioned structure, the second end 52 of each metallic member 50 may be combined with the solder ball 40 stably by a jig pressing operation without any bonding process. Thus, the manufacturing processes may be simplified and speeded up because the jig pressing speed is very high without applying any soldering paste and heat, and the cost is very low.

The steps of packaging and wire bonding are well known in the art. So, detailed descriptions about how the metallic members 50 are packaged and how the wires 55 are bonded will be omitted.

As shown in FIG. 5, an integrated circuit package according to the second embodiment has the rectangular shape, and the structure thereof is similar to that of the first embodiment except that the slots 32 are only formed on two sides of the bottom surface 31 of the encapsulant 30. Thus, the solder balls 40 are only fixed in the slots 32 on two sides of the bottom surface 31 of the encapsulant 30.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An integrated circuit package, comprising:
an integrated circuit on which a plurality of bonding pads is disposed;
an encapsulant, which is made of an insulation material and covers the integrated circuit, wherein a plurality of slots is formed on a bottom surface of the encapsulant;
a plurality of solder balls respectively disposed in the slots on the bottom surface of the encapsulant and protruding from the bottom surface of the encapsulant; and
a plurality of metallic members each having a first end, which is electrically connected to a bonding pad of the integrated circuit, and a second end, which protrudes from the bottom surface of the encapsulant and is bent to intrude into a corresponding one of the solder balls to fix the solder ball.
